(19) United States
(12) Patent Application Publication
(10) Pub. No.: US 2025/0226809 A1
(43) Pub. Date: Jul. 10, 2025

(54) HOLDING DEVICE FOR PIEZOELECTRIC RESONATOR AND POWER CONVERTER COMPRISING SAME

(71) Applicant: COMMISSARIAT A L'ENERGIE ATOMIQUE ET AUX ENERGIES ALTERNATIVES, Paris (FR)

(72) Inventors: Emile BIGOT, Grenoble Cedex 09 (FR); Ghislain DESPESSE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/991,296

(22) Filed: Dec. 20, 2024

(30) Foreign Application Priority Data
Dec. 21, 2023 (FR) FR2314768

(51) Int. Cl. H03H 9/05

(52) U.S. Cl. CPC H03H 9/0595

(57) ABSTRACT

A holding device for a piezoelectric resonator making it possible to minimise the deformation energy which is transmitted to it by the operating resonator, while enabling the resumption of the electrical connections at the electrodes of the resonator. In addition, the holding device proposed tends to reduce the size of the total system, i.e. of the resonator in its holding device, which is a crucial challenge for the desired reduction of volume, in particular when the holding device and the resonator form at least one part of a power converter.

### TECHNICAL FIELD

The present invention relates to the field of power converters, and more specifically, the field of holding devices for piezoelectric resonators, in particular intended to be used as an inductive component within power converters.

### PRIOR ART

Power converters are today omnipresent in daily life, they make it possible to power all electronic devices, whether they are nomadic or not. It is always sought to make them both smaller and less loss-generating.

To do this, one of the solutions proposed consists of increasing their operating frequency, in order to reduce the volume of transitional energy storage components (i.e. passive components). However, limits remain in this frequency increase. They are observed, in particular, alongside magnetic storage components which have intrinsic iron losses and are subjected to the skin effect phenomenon; the two phenomena worsening when the frequency increases. This affects improving the effectiveness of power converters.

In order to exceed these limits, using piezoelectric resonators has been proposed. These resonators are used, for the purpose of constituting power converters, between their resonance frequency and their antiresonance frequency on a specific mode of their structure (for example, transverse (radial), longitudinal, etc.). Between these two frequencies, they have features similar to those of magnetic inductances that are sought to be replaced. The resonance modes used are of a mechanical nature. Thus, the impact of the holding device of the resonator is to be considered, as this can be at the origin of wave leakages (therefore, losses), but also of appearance of novel resonance modes being able to interfere with the system in its operating band. It is thus crucial to find a system ensuring both a correct mechanical holding of the piezoelectric resonator, and a system which also enables a good electrical connection, necessary for using the piezoelectric resonator.

Today, piezoelectric resonators are found in motor vehicles for injecting fuels, for water sprayers, ultrasonic cleaning, precision positioning, plasma generators, but also in the world of telecommunications for producing radiofrequency filters. In the latter case of use, resonators are regularly brought to work on all of the band located between their resonance frequency and their antiresonance frequency on a selected resonance mode, which is less the case for other applications. This is why the prior art discussed below is dedicated to solutions developed to produce radiofrequency filters.

A holding device of a piezoelectric resonator operating on a longitudinal mode is, for example, known from patent document referenced EP1041714 A2. The holding is achieved by means of a mechanical junction made of a material (referenced 40 in FIG. 4 of patent document EP1041714 A2) having an acoustic impedance which is significantly different from that of the resonator. In addition, anchoring points (referenced 40a in FIG. 4 of patent document EP1041714 A2), between the resonator and the holding device, are located a little to the right of centre of the resonator. Physically, these anchoring points correspond to the points where the material displacements are almost zero, but where the stress is maximum for the longitudinal mode, which is addressed by this patent.

This technical solution is interesting, as it makes it possible to confine the acoustic wave without needing to size any elements; it is sufficient simply to produce the central mechanical junction proposed made of a conductive material having acoustic properties different from that of the fixed resonator. Thus, the deformation wave, of low amplitude, as at the centre of the material, is reflected largely between, on the one hand, the resonator and the substrate (referenced 12 in FIG. 4 of patent document EP1041714 A2) and on the other hand, the material constituting the mechanical junction.

However, the mechanical junction between the resonator and its support is sporadic. Indeed, the mechanical resistance of the assembly is poor, and these types of solutions are found to be applied for small resonators having a low mass.

In the case of power conversion, bulk resonators are wanted to be able to be used, in order to store within them, a maximum amount of energy (which depends on the volume of material used). This type of support does therefore not appear robust enough. In addition, in certain applications, a purely planar integration could be desired, which is not possible with the type of mechanical junction that patent document EP1041714 A2 discloses. Moreover, an ancillary electrical connection means must be found, to access the greater potential of the piezoelectric resonator.

A piezoelectric resonator support for electromechanical microsystems, MEMS below, used in radiofrequency is known from patent document referenced CN109546986. The support is such that it implements very slightly rigid fastening structures to hold the piezoelectric resonator. In order to minimise the energy transmitted to the support, the piezoelectric resonator, in the central position, operates on a mode such that it displays nodes at the levels of its anchoring points on the support.

This solution is used when the dimension of the flexible elements of the support becomes too small to be machined directly in the form of rigid bars (which is the case for very-high-frequency resonators). By proposing specific shapes for these flexible elements, their holding rigidity is decreased and the energy transmitted by the resonator to the support is decreased too.

However, it is noted that the support proposed uses a very large surface, which is not desired, in particular, for power conversion. In addition, in order to be effective and to minimise losses, the support imposes the generation of nodes at the periphery of the piezoelectric resonator. Consequently, as the resonator does not work on a first mode, it losses capacity to exchange energy, which is not advantageous when it is sought to develop a solution, the main application of which consists of a power conversion.

Another solution, aiming to minimise the holding losses of a piezoelectric resonator in the case of producing MEMS used in radiofrequency, is described in the scientific article by B. P. Harrington et al., entitled “In-plane acoustic reflectors for reducing effective anchor loss in lateral-extensional MEMS resonators”, and which appeared in J. Micromech. Microeng. 21 (2011) 085021. In order to confine the deformation wave produced by the piezoelectric resonator, a holding device of the resonator is proposed which comprises circular arc-shaped trenches produced on its holding edges. These trenches have characteristic dimensions close to the excitation deformation half-wavelength, so as to form a reflector to confine the deformation wave. In doing so, at the first holding point with the resonator, a quasi-node is generated; then, when the wave propagates to the reflector, the major part of this is returned to the fixing point with the resonator. During its reflection, the wave is phase-shifted by π (or 180°) If the characteristic size is such that the reflected wave forms a displacement node on the edge of the reflector, the reflected wave is returned in line with the first; thus, the reflector is found to accompany the resonator in its deformation, which minimises the losses, due to the holding of the resonator.

Ultimately, the zone where the acoustic reflector is linked with the rest of the frame constitutes a location where wave leakages continue to be dispersed. The benefits of the reflector are considerable all the same, with, according to the authors, a gain of 560% over the mechanical quality factor of the constituted assembly of the resonator and its support.

This holding device is interesting, as it is more compact than that described in patent document referenced CN109546986, and this, through its holding resumption on the side. However, it is observed that the total surface area necessary for holding remains very large, with an occupation close to 1.5 times the surface area of the resonator used. Finally, with the piezoelectric substrate not having to be excited on the parties outside of the resonator, it is necessary to have top and bottom electrodes, which are not superposed on the fixing parts, which reduces the width of the electrical connection plane to the resonator, which, in the case of use for power conversion, needs to be maximised, in order to reduce the electrical impedances of connections (as resistive as inductive). Also, the holding device according to B. P. Harrington et al. assumes zero displacement nodes on the periphery of the resonator, to minimise the energy transmitted to the support.

Therefore, there remains a need in terms of robust mechanical strength means of the resonator, which leave the resonator to vibrate without introducing losses and/or interfering modes, in particular, between its resonance frequency and its antiresonance frequency, on the vibration mode selected.

More specifically, an aim of the present invention is to develop a holding device for a piezoelectric resonator adapted to the stresses induced by the targeted application(s), in particular, including power conversion.

### SUMMARY

To achieve this aim, according to a first aspect of the invention, a holding device for a piezoelectric resonator is provided, the holding device comprising at least two elementary cells intended to be mechanically linked to one another, and to be distributed over a perimeter, inner or outer, of the piezoelectric resonator, at least one, preferably each, elementary cell comprising four bars, of which;
a so-called primary bar by which the holding device is intended to be mechanically linked to the piezoelectric resonator,
two so-called secondary bars, of which:
   a first secondary bar:
      mechanically linked to the primary bar of the elementary cell considered,
      mechanically linked to an elementary cell adjacent to the elementary cell considered, and
      intended to be mechanically linked to an outer frame, and
   a second secondary bar:
      mechanically linked to the primary bar of the elementary cell considered,
      mechanically linked to an elementary cell adjacent to the elementary cell considered, and
      intended to be mechanically linked to the outer frame, and
   a so-called tertiary bar mechanically linking the first secondary bar and the second secondary bar of the elementary cell considered to one another.

According to a second aspect of the invention, an assembly comprising a holding device such as introduced above, and at least one piezoelectric resonator are provided.

According to a third aspect of the invention, a power converter comprising an assembly such as introduced above is provided.

According to a fourth aspect of the invention, a method for sizing a holding device such as introduced above is provided, comprising:
sizing at least one, preferably each, primary bar of at least one, preferably each, elementary cell, such that, with a piezoelectric resonator configured to vibrate in a determined frequency band, the primary bar is resonating, plus or minus 20%, advantageously, plus or minus 10%, with the vibrations of the piezoelectric resonator for any excitation frequency located in said determined frequency band, and/or
sizing at least one, preferably each, from among the first and second secondary bars of at least one, preferably each, elementary cell, such that it has a length substantially equal to a multiple of a half-wavelength for a chosen excitation frequency located in the determined frequency band, and preferably in its centre, or its geometric centre, and have, with respect to their longitudinal axis, a quadratic moment at least four times greater, preferably at least ten times greater, than a quadratic moment of the primary bar with respect to its longitudinal axis, and/or
sizing the tertiary bar of at least one, preferably each, elementary cell, such that it has a length substantially equal to the length of the primary bar of the elementary cell considered, a thickness greater, preferably at least twice greater, than a thickness of the primary bar of the elementary cell considered, and is advantageously adapted, in mechanical impedance, with the first and second secondary bars of the elementary cell considered.

Thus, the invention according to its different aspects proposes a novel holding device for a piezoelectric resonator making it possible to minimise the deformation energy which is transmitted to it by the operating resonator, while enabling the resumption of the electrical connections at the electrodes of the resonator. In addition, the holding device proposed tends to reduce the size of the total system, i.e. of the resonator in its holding device, which is a crucial challenge for the desired reduction of volume, in particular when the holding device and the resonator form at least one part of a power converter.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 schematically represents a cross-sectional view of an embodiment of an elementary cell of a holding device according to the first aspect of the invention and a part of the piezoelectric resonator that the cell equips.

FIG. 1A represents a magnification of the part of FIG. 1 which is framed by a long-short dashed line.

FIG. 2 schematically represents a partial, cross-sectional view of an embodiment of the holding device according to the first aspect of the invention and a part of the piezoelectric resonator that the holding device equips.

FIG. 3 schematically represents the partial, cross-sectional view of an embodiment of the holding device according to the first aspect of the invention which is Illustrated in FIG. 2, and adds graphic illustrations to it, mainly intended to show how transverse waves propagate into the propagation medium that the holding device constitutes.

FIG. 4 schematically represents a top view of a piezoelectric resonator taking the form of a disc and of an embodiment of the holding device according to the first aspect of the invention which equips said piezoelectric resonator.

FIG. 5 schematically represents a top view of a set of square-shaped piezoelectric resonators and a set of holding devices according to the first aspect of the invention which enable a matrixing of said set of piezoelectric resonators.

The drawings are given as examples and are not limiting of the invention. They constitute principle schematic representations intended to facilitate the understanding of the invention, and are not necessarily to the scale of practical applications. In particular, the relative thicknesses of the different constitutive elements of the invention according to its first aspect are not necessarily representative of reality.

### DETAILED DESCRIPTION

Before starting a detailed review of embodiments of the invention, optional features are stated below, which can optionally be used in association or alternatively:

According to an example of the first aspect of the invention, at least one, preferably each, primary bar of at least one, preferably each, elementary cell is of dimensions such that, with a piezoelectric resonator configured to vibrate in a determined frequency band, the primary bar is resonating, plus or minus 20%, advantageously plus or minus 10%, with the vibrations of the piezoelectric resonator for any excitation frequency located in said determined frequency band. That the primary bar resonates at plus or minus 20%, advantageously plus or minus 10%, with the vibrations of the piezoelectric resonator, this means that a frequency offset is enabled between the specific frequency of the primary bar at the fastening point with the piezoelectric resonator, if the piezoelectric resonator was not fastened and the vibration frequency of the piezoelectric resonator which can be any frequency in the determined frequency band. According to the preceding example, the determined frequency band is substantially comprised at most between a resonance frequency and an antiresonance frequency of the piezoelectric resonator on a selected resonance mode.

According to an example of the first aspect of the invention, at least one, preferably each, from among the first and second secondary bars of at least one, preferably each, elementary cell is of dimensions such that it has a length substantially equal to a multiple of a half-wavelength for a chosen excitation frequency, located in the determined frequency band, and preferably in its centre or in its geometric centre, and have, with respect to their longitudinal axis, a quadratic moment at least four times greater, preferably at least ten times greater, at a quadratic moment of the primary bar with respect to its longitudinal axis.

According to an example of the first aspect of the invention, the tertiary bar of at least one, preferably each, elementary cell, is of dimensions such that it has a length substantially equal to the length of the primary bar of the elementary cell considered, a thickness greater, preferably at least twice greater, than a thickness of the primary bar of the elementary cell considered, and is advantageously adapted in mechanical impedance with the first and second secondary bars of the elementary cell considered.

According to an example of the first aspect of the invention, the elementary cell to which the first secondary bar of the cell considered is mechanically linked is different from that to which the second secondary bar of the cell considered is mechanically linked; the holding device thus comprises at least three elementary cells.

According to an example of the first aspect of the invention, said at least two elementary cells are intended to be distributed over the perimeter of the piezoelectric resonator by forming a structure closed on itself, the elementary cell which is mechanically linked to the first secondary bar of the elementary cell considered, is adjacent, in said closed structure, to the elementary cell considered, and the elementary cell which is mechanically linked to the second secondary bar of the elementary cell considered, is adjacent, in said closed structure, to the elementary cell considered, the elementary cells mechanically linked to the elementary cell considered being able to be different from one another.

According to an example of the first aspect of the invention, the primary bar is sized so as to resonate in a first mode, for example, transverse or longitudinal, plus or minus 20%, advantageously plus or minus 10%, for said any frequency located in the determined frequency band. The holding device is thus best adapted to a use of the resonator as a power converter.

According to an example of the first aspect of the invention, at least one bar, preferably each bar, from among the four bars is constituted with the basis of at least one material, preferably isotropic, chosen from among:
a metal, such as brass or copper,
plastic,
ceramic,
a glass fibre-reinforced epoxy resin composition, such as FR-4, and
a crystal.

According to an example of the first aspect of the invention, alterative to the preceding one, at least one bar, preferably each, from among the four bars comprises an isolating material and one or more thin metal layers separated by the isolating material, for example, a wafer for a printed circuit. The holding device according to this example benefits in that a wafer for a printed circuit is inexpensive and/or in that using a wafer for a printed circuit to manufacture the holding device according to the first aspect of the invention makes it possible to use thin metal layers, if necessary machined, to easily enable an operational electrical reconnection, in particular to control the operation of the piezoelectric resonator.

According to an example of the first aspect of the invention, alternative to the two preceding ones, at least one bar, preferably each bar, is constituted with the basis of the same piezoelectric material, preferably transverse isotropic, as that in which is intended to constitute the piezoelectric resonator. The holding device according to this example can advantageously only constitute one part or a part of one single holding with the electrical resonator.

According to an example of the first aspect of the invention, the primary bar is intended to be mechanically linked to the piezoelectric resonator at one first connecting point located substantially between a first end and a second end of the primary bar.

According to an example of the first aspect of the invention, the primary bar is intended to be mechanically linked to the piezoelectric resonator through a lug, the mass of the lug being, if necessary, considered for the sizing of the primary bar.

According to another example of the first aspect of the invention, the primary bar has a symmetry with respect to an axis normal to the perimeter of the resonator around the fastening point.

According to an example of the first aspect of the invention:
the first secondary bar of the elementary cell considered is mechanically linked by a first of its two ends to the first end of the primary bar of the elementary cell considered, is mechanically linked by a second of its two ends, both to a second end of the secondary bar of an elementary cell which, from among said at least two elementary cells, is adjacent to the elementary cell considered, and is intended to be mechanically linked to the outer frame, and
the second secondary bar of the elementary cell considered is mechanically linked by a first of its two ends to the second end of the primary bar of the elementary cell considered, is mechanically linked by a second of its two ends, both to a second end of the first secondary bar of an elementary cell which, from among said at least two elementary cells, is adjacent to the elementary cell considered, and intended to be mechanically linked to the outer frame.

According to an example of the first aspect of the invention, the tertiary bar of the elementary cell considered mechanically links to one another, the first end of the first secondary bar of the elementary cell considered and the first end of the second secondary bar of the elementary cell considered.

According to an example of the first aspect of the invention, the tertiary bar of each elementary cell is located to the right of and at a distance from the primary bar of the elementary cell considered, and is intended to be located, relative to the outer or inner perimeter of the piezoelectric resonator that it contributes to hold, at a greater distance than the primary bar of the elementary cell considered.

According to an example of the first aspect of the invention, said at least two elementary cells are distributed over the perimeter of the piezoelectric resonator such that the latter by operating, exerts an excitation of the same amplitude at plus or minus 20%, preferably plus or minus 10%, and/or of the same phase, at plus or minus 30°, preferably plus or minus 15°.

According to an example of the first aspect of the invention, each primary bar has a thickness at least 10 times greater than the deformation amplitude that it undergoes, due to the operation of the piezoelectric resonator.

According to an example of the second aspect of the invention, the piezoelectric resonator of the assembly is constituted with the basis of PZT.

According to another example of the second aspect of the invention, the piezoelectric resonator of the assembly is constituted with the basis of LNO (lithium niobate).

According to an example of the third aspect of the invention, the piezoelectric resonator is configured to vibrate in at least one of its first vibration modes, for example, its transverse vibration mode and/or its longitudinal vibration mode.

According to an example of the third aspect of the invention, the piezoelectric resonator has a resonance frequency and an antiresonance frequency, different from one another, and is configured to operate between its resonance frequency and its antiresonance frequency.

By an element with the basis of a material A, this means an element comprising this material A and optionally other materials.

By a parameter “substantially equal to/greater than/less than” a given value, this means that this parameter is equal to/greater than/less than the given value, plus or minus 20%, even plus or minus 10% of this value. By a parameter “substantially between” two given values, this means that this parameter is, as a minimum, equal to the smallest given value, plus or minus 20%, even plus or minus 10% of this value, and, as a maximum, equal to the greatest given value, plus or minus 20%, even plus or minus 10% of this value.

By a mechanical connection between two elements or bars, this means that these two elements or bars contact one another without mechanical clearance in at least one connecting point or zone, or contact point or zone. Preferably, two elements or bars mechanically linked to one another directly contact one another: in which case, direct mechanical connection, or elements or bars directly mechanically linked to one another, can be referred to. In this way, mechanical stresses, in particular, linked to a displacement of at least one of the two elements or bars mechanically linked to one another, propagate to the other element or bar, this propagation of mechanical stresses depend, in particular from their nature and their amplitude, on the designs (at least shape and dimensions) of the elements or bars in question.

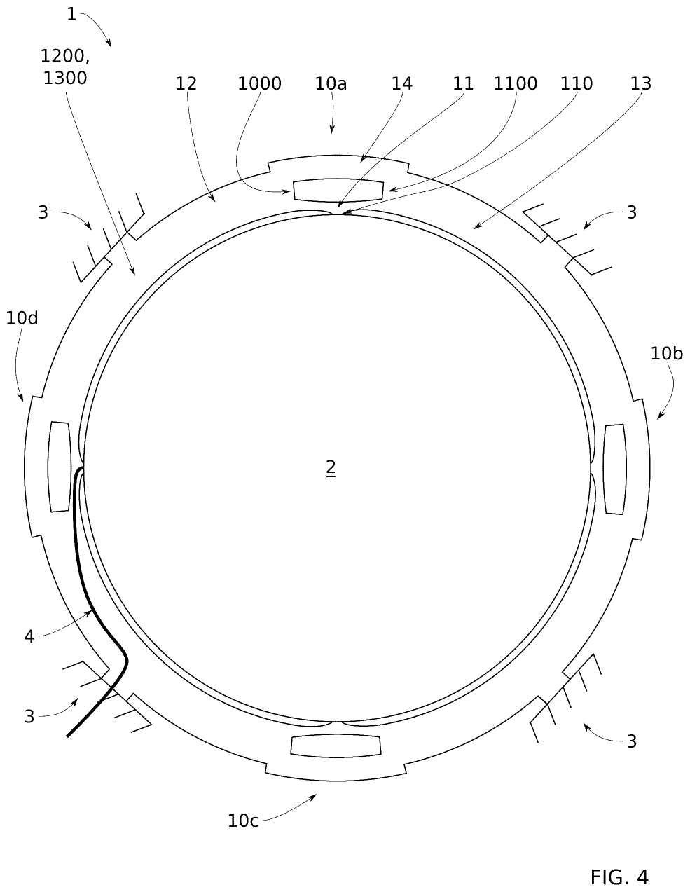

By operating nodes, this means noteworthy zones of the holding device according to the first aspect of the invention, which are not necessarily sporadic, but which can, on the contrary, be extended, their extension however remaining small, for example ten times less, relative to the dimensions of the bars. The operating nodes of the holding device according to the first aspect of the invention, are for example, located in the zones which, in FIG. 4, are delimited by the oval curves in bold dashes, each of these zones comprising an operating node.

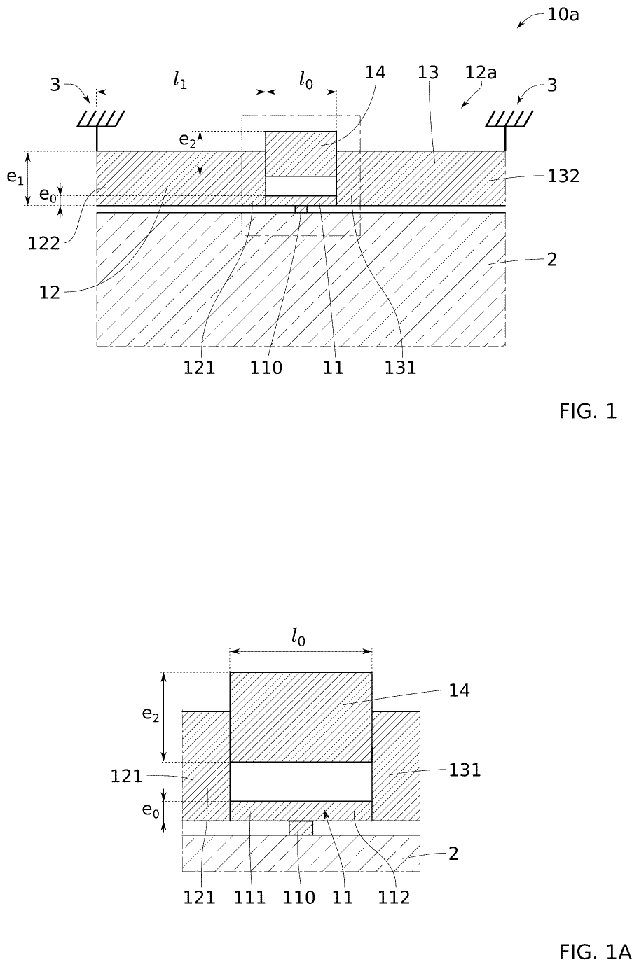

In reference to FIGS. 1 and 1A, one of the aims followed by the present invention consists of providing a holding device 1 (sometimes called “fixing” below) of a piezoelectric resonator 2 on an outer frame (or package) 3, which is adapted to the stresses induced by certain applications, and in particular, power conversion. The holding device 1 is more specifically intended to link, or also to interface, mechanically, the resonator 2 and the frame 3 to one another. The frame 3 is preferably fixed and non-deformable under mechanical stresses that it can undergo, due to the vibratory deformations of the piezoelectric resonator 2, to which it is mechanically linked via the holding device 1. Thus, the holding device 1 and the frame 3 are intended to form together, for the resonator 2, an operational qualifiable support, in particular relative to a targeted application of the resonator 2, and more specifically, of its vibrations.

Preferably, the holding device 1 must be capable of holding at least one resonator 2, even each resonator 2 from among a plurality, in several connecting (or contact) points 110. In this way, it is made possible, according to the present invention, to isolate the piezoelectric resonator 2 from its working environment 3, by preserving a loss rate due to the relatively low anchoring of the resonator 1. Consequently, it is possible, according to the present invention, to return the holding of the isostatic/hyperstatic resonator 2 relative to its support, which is not the case of the solutions of the prior art. In addition, the size of the support 2 should ideally be reduced to the strict minimum, such that the total power density of the resonator 2 with its holding device 1 mounted on the frame 3 can be maximised, which is not the case of the solutions proposed by patent document referenced CN 109546986 and by the article by B. P. Harrington et al.

Though its nature, a piezoelectric resonator 2 generates, by operating, deformation waves which propagate to the frame 3 via the holding device 1. By correctly using the waves produced, the deformation energy propagated to the frame 3 can be reduced, and therefore the losses linked to the propagation of these reduced waves; it is this that makes it possible to achieve the holding device 1 according to the first aspect of the present invention. In addition, through the generation of displacement nodes extended to the connecting interfaces between the holding device 1 and the frame 2, a mechanical isolation of the resonator with respect to the frame is obtained. This making it possible to avoid the resonating of the element of the frame, being able to cause an increase of the absorption of energy in the working frequency band.

As clearly will appear below, contrary to the solutions of the prior art, the holding device 1 proposed in this case, does not impose an interfacing between the resonator 2 and the frame 3 on almost zero deformation nodes, the resonator 2 held by the holding device 1 according to the present invention can advantageously work on one of its first vibration modes, where the exchangeable energy is maximum, for example, the transverse mode, or more specifically, the radial mode, of a resonator taking the form of a disc.

In addition, the holding device 1 according to the first aspect of the invention makes it possible to reduce the manufacturing costs of the assembly comprising the holding device 1 and the piezoelectric resonator 2.

Furthermore, it is interesting to use simple resonator 2 shapes, squares as well as rectangular or circular, or disc- or ring-shaped.

Also, a potentially complex machining of the fixing 1 making it possible to minimise the energy transmitted by the resonator 2 to the frame 3 can be expensive to produce in the material with the basis of which the resonator 2 is constituted. Subsequently, it is advantageous to be able to use a different material, less expensive and/or easier to machine, to manufacture the holding device 1. These materials can, for example, be brass, copper, plastic, a ceramic, a glass fibre-reinforced epoxy resin composite, such as FR-4 (“Flame Retardant 4”), a crystal, etc.

Furthermore, the holding device 1 comprising at least two elementary cells 10a, 10b and 10c intended to be mechanically linked to one another, and to be distributed over a perimeter, inner or outer, of the piezoelectric resonator 2, and at least one, preferably each, elementary cell 10a, 10b, 100 comprising four bars 11, 12, 13 and 14, the latter can be constituted of one same material or of different materials and/or have varied cross-sections (square, as well as rectangular, circular, etc.). Also, if the considerations below mainly relate to bars of rectangular cross-section and made of one same material, the holding device 1 according to the first aspect of the invention is not limited to this example, given for information.

An elementary cell 10a of the holding device 1 is schematised in FIG. 1, which illustrates, on the one hand, the mechanical connection between the elementary cell 10a and the resonator 2, on the other hand, the mechanical connections between the elementary cell 10a and the frame 3. In FIG. 1, the piezoelectric resonator 2 having to be held is only partially represented, to have an enlarged view of the elementary cell 10a. Then, to generalise, a perimeter of the developed resonator 2 is considered, knowing that the shape of the resonator 2 can be round, square, rectangular, oval, that of a disc, that of a ring or any other. In FIG. 1, the elementary cell 10a is represented rigid, but it can be curved, for example to follow a rounded shape of the perimeter of the resonator 2.

Each elementary cell 10a, 10b, 10c, etc. of the fixing 1 can be seen as constituted of an assembly of three types of vibratory elementary bars, referenced below Bᵤ₀, Bᵤ₁ and Bᵤ₂, of which a bar of a first type, called primary bar 11, two bars of the second type, called secondary bars 12 and 13, and a bar of a third type, called tertiary bar 14. The qualifiers “primary”, “secondary” and “tertiary” make it possible to distinguish the types of bars from one another, and not to establish relative importance levels between types in of bars.

At each connecting point 110, referenced below aᵤ, between an elementary cell 10a, 10b, 10c and the resonator 2, the elementary cell is mechanically linked with the resonator 2. Furthermore, each of the edges of the elementary cell 10a, that is each from among second ends 122 and 132 of the bars Bᵤ₁, referenced 12 and 13 in FIG. 1, the elementary cell 10a is linked to the frame 3. These mechanical connections can serve to implement the resonator 2 and its fixing 1 in its working environment comprising the frame 3.

At least two elementary cells are distributed over the perimeter of the resonator 2 to be held. In FIG. 4, four holding devices 1 are represented, which form, as will be seen below, a structure closed on itself, adapted to the circular perimeter of a resonator 2 taking the form of a disc. It is however considered that such a closed structure can be constituted of two elementary cells only. For example, starting with the example illustrated in FIG. 4, it is considered that a closed structure can be constituted of two cells which, from among the four represented in FIG. 4, are opposite to one another.

It is highly preferable that, at all the connecting points 110 between the elementary cells 10a, 10b, 10c and 10d and the resonator 2, the resonator exerts, in operation, substantially the same excitation. To satisfy this preference, it will be seen below that, according to the design (shape and dimensions) of the resonator 2 to be held and from the vibration mode, that it is sought to use, a minimum number of elementary cells to be distributed over the perimeter of the resonator 2 can be greatly desired, even imposed. More specifically, the resonator 2 in operation exerts an excitation, substantially of the same amplitude, for example, at plus or minus 20%, preferably plus or minus 10%, and/or substantially of the same phase, at plus or minus 30° (or plus or minus 0.52 radians), preferably plus or minus 15°. For example, as developed below, for a resonator 2 taking the form of a disc over the circular perimeter of which elementary cells 10a, 10b, 10c and 10d are to be distributed to form the holding device 1 according to the first aspect of the invention, it is preferable that the connecting points 110 between the fixing 1 and the resonator 2 are substantially evenly distributed, i.e. at equidistance from the centre of the resonator 2 and at equidistance from their first neighbouring one(s), for example, at plus or minus 20%, preferably plus or minus 10%.

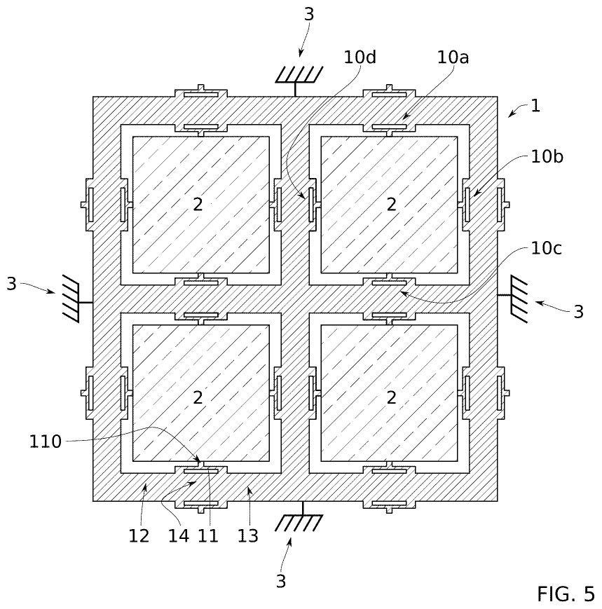

Preferably, in reference to FIGS. 4 and 5, the holding device 1 comprises a plurality of elementary cells 10a, 10b, 10c and 10d, each comprising, or consisting of, an assembly of a primary bar 11, of two secondary bars 12 and 13 of a tertiary bar 14, distributed over the perimeter of the resonator 2 by forming a structure closed on itself.

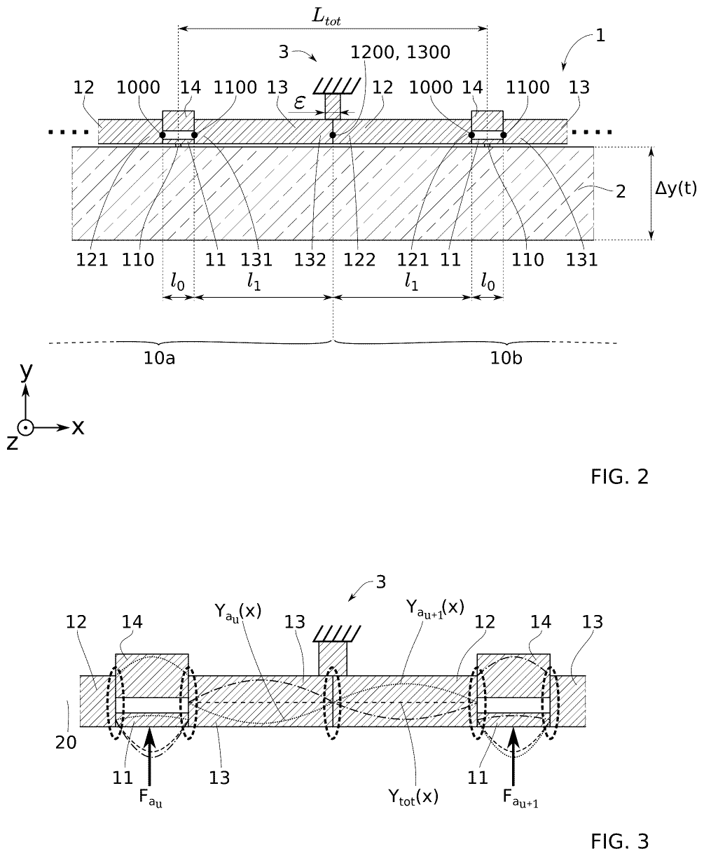

FIG. 2 represents two elementary cells 10s and 10b adjacent to one another (or consecutive), if necessary, in said structure closed on itself, which are mechanically connected with the resonator 2 over its perimeter being deformed along the axis y (see FIG. 2) when the resonator is in operation.

More specifically, the diagram of FIG. 2 illustrates so-called operating nodes, sometimes referenced below nᵤ₀ and nᵤ₁, of which at least two nodes of a first type nᵤ₁ comprising, for example, the points referenced 1000 and 1100, and nodes of a second type nᵤ₀ comprising, for example, the points referenced 1200 and 1300. By primary bar 11, the two operating nodes 1000 and 1100 must preferably be respectively located in the bold dashed oval zones, which are illustrated in FIG. 3 to the right of the ends 111 and 112 of each primary bar 11, and to the right of the ends of each tertiary bar 14, and in particular, between the primary bar 11 in question, and the tertiary bar 14 in question. In reference to FIGS. 2 and 3, each operating node 1200 must preferably be located in a bold dashed oval zone, which is illustrated in FIG. 3 between the secondary bar 12 of a first of the two elementary cells illustrated, and the secondary bar 13 of the adjacent elementary cell, and in particular, to the right of a second end 122 of the first secondary bar 12 of the elementary cell to the left and to the right of the frame 3. Still in reference to FIGS. 2 and 3, each operating node 1300 must preferably be located in a bold dashed oval zone, which is illustrated in FIG. 3 between the secondary bar 13 of a first of the two elementary cells illustrated and the secondary bar 12 of the adjacent elementary cell, and in particular, to the right of a second end 132 of the second secondary bar 13 of the cell 10a and the right of the frame 3. The operating nodes 1200 and 1300 are preferably distant from one another by less than plus or minus 30%, advantageously by less than plus or minus 10%, of the excitation wavelength of the resonator 2; they are preferably substantially combined with one another. This preference is met, as soon as the secondary bars have one same length, are linked in pairs by one of their ends, and that the secondary bars are mechanically linked to the frame 3 by the ends of the elementary cell to which they belong.

It is sought that these operating nodes 1000, 1100, 1200 and 1300 correspond to zones where the deformation amplitude of the bars Bᵤ₀, Bᵤ₁ and Bᵤ₂ is almost zero for a determined excitation frequency of the resonator 2 taken in a determined frequency band, typically taken in its useful band, for example, between its resonance frequency and its antiresonance frequency. For that, the primary 11 and secondary 12 and 13 bars of at least one elementary cell 10a, preferably of each elementary cell 10a, 10b, 10c, etc., can advantageously be sized such that, for an excitation signal of the resonator 2 at the determined excitation frequency of the resonator 2, the operating nodes 1000, 1100, 1200 and 1300 are actually located in the locations drawn in FIG. 2, or more generally, in a respective zone from among the bold dashed oval zones illustrated in FIG. 3, at plus or minus 30%, advantageously plus or minus 10%, of the excitation wavelength of the resonator 2.

Another way of expressing this sought technical effect consists of imposing, in these operating nodes 1000, 1100, 1200 and 1300, an amplitude movement less than 10% of the maximum deformation amplitude generated in the secondary bars 12 and 13.

Once this first sizing is performed, or alternatively, the tertiary bar 14 of at least one elementary cell 10a, preferably the tertiary bar 14 of each elementary cell 10a, 10b, 10c, etc. is preferably sized, in order to favour the propagation of mechanical waves coming from the secondary bars 12 and 13 to the tertiary bars 14 rather than to the primary bars 11.

These sought technical effects, in order to minimise the mechanical energy transmitted by the resonator 2 to the frame 3 via the fixing 1, are achieved, thanks to the holding device 1 according to the first aspect of the invention, by using three elementary principles present below briefly, before being presented lower in a more detailed way.

In reference to FIG. 3, the first principle to use comes from that the force \vec{Fₐ_{ᵤ₍₊₁₎}} transmitted by the vibrating resonator 2 to the primary bar(s) 11 is proportional to the mechanical impedance Z of the primary bar(s) 11 that multiplies the displacement speed \vec{v} of the operating nodes 1000 and 1100 of the first type nᵤ₁, this displacement speed being substantially equal to the deformation speed of the excited piezoelectric resonator 2, due to the mechanical connections 110 between the fixing 1 and the resonator 2: \vec{F}=Z.\vec{v}.

As has been sought to limit, to the maximum, the energy transmitted by the resonator 2 to the frame 3 via the fixing 1, it is advantageous that the primary bars 11 are sized, such that they are resonated with the vibrating resonator 2 to guarantee the existence of the nodes 1000 and 1100 of the first type nᵤ₁. To do this, the primary bars 11 must be sized, such that they have an almost zero mechanical impedance. Thus, the mechanical impedance Z can be chosen, such that the working frequency and for the maximum displacement generated at the periphery of the resonator, the power supplied by the resonator to the support is less than 30% of the power lost internally via its mechanical losses. The resonating of the elements 11 makes it possible to minimise the transmission of mechanical energy from these elements to the elements 12, and therefore ultimately the energy extracted at the resonator 2 by the holding device 1 in its in working environment 3.

In reference to FIGS. 2 and 3, the second principle to use consists of making the deformation waves induced at the consecutive mechanical connections interfere with one another, sometimes referenced below aᵤ et aᵤ₊₁, between the elementary cells 10a and 10b and the resonator 2. This contributes advantageously to confining the deformation waves, such that these remain, in the main, in the fixing 1 and not propagating to the frame 3 by the nodes nᵤ₀ of the second type. This function is performed by the secondary bars 12 and 13, sometimes referenced below Bᵤ₁. Indeed, by making two deformation waves induced at the two consecutive mechanical connections aᵤ and aᵤ₊₁ interfere with one another, it is ensured that the operating nodes 1200 and 1300 are extended zero displacement nodes. To do this, each of the first and second secondary bars 12 and 13 of at least one elementary cell 10a, preferably of each elementary cell 10a, 10b, 10c, etc., can be sized, so as to have a length substantially equal to a multiple of a half-wavelength of the excitation frequency, optionally average, of the resonator 2 and/or so as to have a quadratic moment, with respect to their longitudinal axis, at least four times greater, preferably at least ten times greater, then a quadratic moment of the primary bar 11 with respect to its longitudinal axis.

The third principle uses the fact that the propagation of a deformation wave coming from a primary bar Bᵤ₀ to a secondary bar Bᵤ₁ is not equivalent to that of a wave coming from a secondary bar Bᵤ₁ to a primary bar Bᵤ₀. The use of this third principle aims, there again, in particular to minimise the interfering of deformation waves, which would lead to an increase of the energy transfer of the resonator 2 to the frame 3 via the fixing 1. This aim is mainly achieved by sizing of the tertiary bars Bᵤ₂. More specifically, to achieve the aim set, each tertiary bar 14 can:
have a length substantially equal to the length of the primary bar 11, and/or
have a thickness (or more generally, a cross-section surface) greater, preferably at least twice greater, than a thickness (or more generally, a cross-section surface) of the primary bar 11, and/or
be adapted in mechanical impedance with the first and second secondary bars 12 and 13.

Below, each of the three principles introduced above are returned to below, in more detail.

### Minimisation of the Energy Transfer Between the Frame and the Resonator by the Primary Bas Bᵤ₀

At the contact points 110 between the holding device 1 and the resonator 2, these points being referenced below aᵤ and aᵤ₊₁ for two adjacent elementary cells u and u+1, transverse mechanical waves of amplitude ΔY₀ are generated at the pulsation a in the material constituting the holding device 1 and therefore, first, in the bars Bᵤ₀ and B₍ᵤ₊₁₎₀. In this case, all of the holding device 1 is sized to operate with a resonator 2 working over a well-defined frequency range, between its resonance frequency and its antiresonance frequency on a chosen mode; the interval comprising the deformation pulsation (is therefore known.

Initially, it will be considered that the deformation wave induced at each of the connecting points aᵤ, aᵤ₊₁, etc. is substantially identical. Indeed, it can be considered that all of the application points of the deformation, i.e. of the connecting points aᵤ, aᵤ₊₁, etc., behave strictly in the same way by placing said points relative to the resonator 2, and more specifically, relative to its perimeter. Thus, the resonator 2 can be considered as a displacement generator Δy of amplitude ΔY₀ in aᵤ₍₊₁₎, such that:

$$Δ y ( {a}_{u ( + 1 )} , t ) = Δ {Y}_{0} {e}^{i ( ω t + Φ )} , etc .$$

With the aim of generating a mainly transverse mechanical wave in the fixing 1, the primary bar 11, referenced Bᵤ₀, acting as a support rod, must be substantially in a tangential direction, at plus or minus 40°, preferably plus or minus 20°, at the local perimeter of the resonator 2, knowing that the primary bar 11 can itself have a curve. This support rod Bᵤ₀ must have a main resonance mode, close to the deformation pulsation ω with respect to its excitation in aᵤ₍₊₁₎, and in particular, facing the direction of this excitation; typically, if the resonator 2 has a transverse movement, and for example, radial, and that the primary bar 11 is at least locally tangential at the perimeter of the resonator 2, thus the primary bar 11 mainly operates in flex mode, and the main resonance mode must thus be considered in flex mode. Then at the same resonance frequency, typically at the same value of the parameter

$$\sqrt{\frac{k}{m}} ,$$

where m is the equivalent mass returned to the beam tip of the primary bar 11, and where k is its rigidity, the lower said mass is, the lower the rigidity is, and the lower the forces transmitted by this rigidity are. Thus, from among the possible geometric solutions for the primary bar 11, it is advantageous to take the smallest one. This optimal choice regarding the transmission of mechanical forces is however limited by:
The manufacturing options, for example, relating to the minimum thickness which can be achieved according to the manufacturing method selected, and the associated cost of the precision/finish,
The mechanical stresses in the primary bar 1, and
The robustness of the primary bar 11, and more generally, of the fixing 1 (shock resistance, for example).

To minimise the mechanical stresses in the material constituting the primary bar 11, it is advantageous that its displacement amplitude is low before the thickness of the primary bar 11; typically, a primary bar 11 thickness at least 10 times greater than the deformation amplitude will be chosen, for example average, of the piezoelectric resonator in its excitation frequency band.

By considering each primary bar 11 as an excited beam on a flex mode, the energy transmitted, to the holding device 1 over an operating period T at the primary bar 11, depends both on the displacement speed \vec{v(aᵤ₍₊₁₎)} of the primary bar, which is imposed by the resonator 2, and of the force \vec{F(aᵤ₍₊₁₎)} that the primary bar 11 will generate opposite its displacement:

$${E}_{transmitted} ( {a}_{u} ( + 1 ) ) = {\int }_{T} \vec{F ( {a}_{u ( + 1 )} )} . \vec{v ( {a}_{u ( + 1 )} )} dT$$

It is thus understood that minimising the opposing force of each primary bar 11 at its displacement point makes it possible to reduce the total energy supplied to the rest of the holding device 1 by the resonator 2.

It is the first principle brought into play in the scope of the sizing of the fixing 1 according to the first aspect of the invention, and which aims to minimise the energy supplied to the rest of the fixing 1 by its first primary bars 11. The rigidity opposed by the primary bars 11 on the resonator 2 must therefore be low. In the case of using primary bars 11 used in flex mode, decreasing their quadratic moment 1, makes it possible to decrease the opposing force, and thus to minimise the energy transmitting to the fixing 1 by the resonator 2. Also, making the primary bars 11 resonate at the excitation frequency of the resonator 2 makes it possible to crease the equivalent rigidity of these bars 11, and therefore the energy transmitted to the rest of the fixing 1. It is therefore interesting to develop primary bars 11 such as these resonate at the operating frequency of the resonator 2 and accompany its movement.

The sizing of the primary bars 11 is performed, therefore such that these resonate for a frequency located in the working frequency band of the resonator 2. It will also be sought to make each primary bar 11 resonate on a first mode. In this way, it is attempted to limit, to the maximum, the presence of other resonance modes, which could oppose the displacement of the primary bars 11 in the working range between the resonance frequency and the antiresonance frequency of the resonator 2.

Subsequently, it is sought to minimise the energy transmitted from the primary bars 11 to the secondary bars 12. Knowing that the primary bars 11 resonate or are close to the resonance (at plus or minus 20%, advantageously, plus or minus 10%) at the working frequency of the resonator 2, of the quasi-nodes, i.e. of the points (or zones) where the displacement of the transverse wave developed is very low, are generated at the two operating nodes 1000 and 1100 linked to each primary bar 11. Indeed, at these locations, the stresses generated by the mechanical deformation waves are maximum for each primary bar 11. Yet, if the secondary bars 12 and 13 mechanically linked to each primary bar 11 have a greater quadratic moment, for example, due to a thickness greater than that of the primary bar 11, the displacement of the secondary bars 12 and 13 produced by the displacement of the primary bar 11 of each elementary cell is lower at iso-stress. Thus, due to a lineic rigidity rupture between the primary bar 11 and the secondary bars 12 and 13 of each elementary cell, most of the energy supplied by the resonator 2 remains confined at the primary bar 11 and propagates slightly to the rest of the fixing. It is moreover by reflecting the transverse deformation wave at the two operating nodes 1000 and 1100, that the primary bar 11 of each elementary cell resonates.

Interfering of the Deformation Waves for their Confinement by the Secondary Bars Bᵤ₁

Through the distribution, preferably substantially symmetrical, even periodical, of the elementary cells 10a, 10b, 10c, etc. of the holding device 1, even through the periodic structure that it forms, relative to the perimeter of the resonator 2, the holding device 1 induces interferences within it between the deformation waves produced at two consecutive connecting points 110 aᵤ and a₍ᵤ₊₁₎, with the resonator 2. Indeed, the waves which enter at these consecutive connecting points 110 aᵤ and a₍ᵤ₊₁₎ propagate over the primary bars 11. Bᵤ₀ and B₍ᵤ₊₁₎₀ of two consecutive elementary cells, over an equivalent distance, in the propagation medium, at an excitation quarter-wavelength of the resonator 2, forming quasi-nodes at the operating nodes 1000 and 1100 of the first type nᵤ₁. Then, the waves propagate over the secondary bars 12 and 13 to ultimately meet at the operating nodes 1200 and 1300 of the second type nᵤ₀ which are substantially combined with one another, and located between two consecutive elementary cells 10a and 10b.

By choosing secondary bars 12 and 13 having a length substantially equal to a multiple of a half-wavelength, thus the meeting of these waves at the operating nodes 1200 and 1300 of the second type nᵤ₀ is performed by interference of a destructive nature between the waves (see equations below). Ultimately, the phase shift induced creates a zero displacement node extended at the operating nodes 1200 and 1300 of the second type nᵤ₀.

An extended zero displacement node is defined, in this case, as an enlarged zone (represented, for the example, in FIG. 3, by each of the bold dashed oval zones), in which the displacement is substantially zero, typically, over a distance of λ/10, where λ is optionally average deformation wavelength. The displacement in an extended zero displacement node is preferably at least 10 times less than the maximum displacement at the maximum displacement point of the fixing 1. This makes it possible to be tolerant on the actual anchoring point at the frame 3, as well as on the working frequency induced by the vibration of the resonator 2. This is, in particular, necessary in the case of using a strongly coupled piezoelectric resonator 2 being able to be brought to operate over a wide frequency range (typically 20% of frequency variation). The extended zero displacement nodes are obtained at the interconnecting points 1200 and 1300 of the second type nᵤ₀, limiting the transmission of waves to the frame 3 in these nodes 1200 and 1300. Through the repetitive, even periodic structure, of the fixing 1, the effect produced at the operating nodes 1200 and 1300 which are located between the two consecutive elementary cells 10a and 10b illustrated partially in FIG. 2, is also obtained on the operating nodes 1200 and 1300 which are located between two other elementary cells which are consecutive to one another, in the structure that the fixing 1 forms. These operating nodes 1200 and 1300 of the second type nᵤ₀ can be referenced below: n₍ᵤ₋₁₎₀ n₍ᵤ₊₁₎₀, etc.

According to the same reflection conducted on the interfering of the waves generated at the contact points 110 between the holding device 1 and the resonator 2, it can be said that, by construction, each secondary bar 12 and 13 of each elementary cell 10a, 10b, 10c, etc. obtains a relatively rigid rigidity over the working frequency (where the nature of the interference is of the destructive type, i.e. that for a certain internal stress, the relative displacement will be lower than for the case of the propagation of one single wave, in particular, over its periphery). Thus, the confinement of the wave during its transmission between the primary bar 11 and the secondary bars 12 and 13 of each elementary cell is increased.

Ultimately, by returning to the general equation of the arrow in a bending beam developed in Euler-Bernoulli beam theory, it is shown that the structure of the fixing 1 makes it possible to increase the relative rigidity of the secondary bars and produces zero displacement nodes extended to the connecting levels between the fixing 1 and the frame 3.

More specifically, the general equation of the transverse displacement of an excited beam at the pulsation w can be written:

$$y ( x , t ) = ( A sin ( β x ) + B cos ( β x ) + C sinh ( β x ) + D cosh ( β x ) ) {e}^{i ( ω t + Φ )}$$

$$Y ( x ) = ( A sin ( β x ) + B cos ( β x ) + C sinh ( β x ) + D cosh ( β x ) )$$

by referencing β the wave number, ϕ the phase shift, and A. B, C and D of the parameters depending on the limit conditions imposed on the beam.

It is assumed that, by construction, the deformation waves emitted at the contact points 110 between the holding device 1 and the resonator 2 are substantially the same. Thus, at the operating nodes 1200 and 1300 of the second type nᵤ₀ which are located between two elementary cells consecutive to one another, the two waves will have travelled the same path, but in two opposite directions (x increasing or x decreasing in FIG. 2). By assuming that the materials chosen for the secondary bars are substantially isotropic and that these bars are substantially or the same shape and dimensions, optionally at an axis or near plane symmetry, the deformed views produced by these two waves are thus substantially equivalent in amplitude.

By assuming that at the operating nodes 1000 and 1100 of the first type nᵤ₁, a node is actually generated by the incident wave from the connecting point 110 in question, and that the energy transmitted to the secondary bars 12 and 13 is low. On the one hand, embedding conditions are found at the nodes nᵤ₁ and on the other hand, a sporadic connecting condition is found at the nodes nᵤ₀, as the holding device 1 is connected to the frame over its perimeter in nᵤ₀. This gives the following limit conditions for calculating the deformed view of the bars 12 and 13:

$$\text{?} ( {n}_{u 1} ) ≅ 0$$

$$\frac{\partial \text{?} ( {n}_{u 1} )}{\partial x} ≅ 0$$

$$\text{?} ( {n}_{u 0} ) ≅ 0$$

$$M ( x ( {n}_{u 0} ) , t ) = EI \frac{{\partial }^{2} Y ( {n}_{u 0} )}{\partial {x}^{2}} ≅ 0$$

$$\text{?} \text{indicates text missing or illegible when filed}$$

Under a reference point such that the node 1100 of the elementary cell in question is located at x=0, and according to the embedding events at the node 1100 and sporadic connections at the nodes 1200 and 1300, the solution of the deformed view of the secondary bars 12 and 13 is as follows:

$${Y}_{a u} ( x ) = {Y}_{0} ( ( cos ( β x ) - cosh ( β x ) ) - 0.9825 ( sinh ( β x ) - sin ( β x ) ) )$$

$$β {l}_{1} = 3.927$$

Around the mechanical connection between the fixing 1 and the frame 3, therefore for x=l₁+∈ with ∈ small (see FIG. 2), and more specifically for ∈ less than 5% of l₁, the deformed view due to the deformation wave produced at this connection can be written as follows:

$${Y}_{a u} ( {l}_{1} + ϵ ) = {Y}_{0} ( ( cos ( β ( {l}_{1} + ϵ ) ) - cosh ( β ( {l}_{1} + ϵ ) ) - 0.9825 ( sinh ( β ( {l}_{1} + ϵ ) ) - sin ( β ( {l}_{1} + ϵ ) ) ) )$$

$$- 0.9825 ( sinh ( β {l}_{1} ) cosh ( βϵ ) + cosh ( β {l}_{1} ) sinh ( βϵ ) - sin ( β {l}_{1} ) cos ( βϵ ) - cos ( β {l}_{1} ) sin ( βϵ ) ) )$$

$$\text{?} ( {l}_{1} - ϵ ) ≅ {Y}_{0} ( ( cos ( β {l}_{1} ) - βϵ sin ( β {l}_{1} ) - cosh ( β {l}_{1} ) + βϵ sinh ( β {l}_{1} ) )$$

$$- 0.9825 ( sinh ( β {l}_{1} ) + βϵ cosh ( β {l}_{1} ) - sin ( β {l}_{1} ) - βϵ cos ( β {l}_{1} ) ) ) + O ( ϵ )$$

$$\text{?} ( {l}_{1} - ϵ ) ≅ {Y}_{0} ( ( β ϵ sinh ( β {l}_{1} ) - βϵ sin ( β {l}_{1} ) ) - 0.9825 ( βϵ cosh ( β {l}_{1} ) - βϵ ( β {l}_{1} ) ) )$$

$$\text{?} \text{indicates text missing or illegible when filed}$$

For the wave propagating in the opposite direction, i.e. from the connecting point aᵤ₊₁ of the adjacent elementary cell to the operating nodes 1200 and 1300 of the second type nᵤ₀, x=l₁−∈ around the mechanical connection with the frame 3. It is thus possible to write the corresponding formula and to calculate the superposition of the two deformation waves coming from the connecting points aᵤ and aᵤ₊₁ of the two elementary cells in question around their meeting point nᵤ₀:

$${Y}_{tot} ( {n}_{u 0} ) = \text{?} ( {l}_{1} - ϵ ) + \text{?} ( {l}_{1} - ϵ )$$

$${Y}_{tot} = 0 + O ( ϵ )$$

$$\text{?} \text{indicates text missing or illegible when filed}$$

It can therefore be said that, around each of the operating nodes 1200 and 1300 of the second type nᵤ₀, extended zero displacement nodes are induced due to repetition, optionally periodic, of the elementary cells 10a, 10b, 10c, etc. As the vibration around the operating nodes 1200 and 1300 is subsequently very low, it almost does not propagate to the rest of the frame 3 and remains confined in the fixing 1.

Then, in reference to FIG. 2, it can be considered that the wave emitted at the connecting point 110 (referenced aᵤ₊₁), consecutive to a first connecting point 110, referenced aᵤ, will continue to interfere with the wave emitted at the first connecting point 110 (referenced aᵤ) in the secondary bar 13 of the elementary cell 10a and, conversely, the wave emitted at the first connecting point 110, referenced aᵤ₁ will interfere with the wave emitted from the second connecting point aᵤ₊₁ in the secondary bar 12 of the second elementary cell 10b.

As above, the interference is of a destructive nature, which tends to limit the displacement amplitude of the secondary bars 12 and 13, and therefore contributes to minimising losses which are functions of the quantity of material displaced.

This phenomenon is illustrated through FIG. 3. The following can be observed there:
in long-short dashes, a first deformation wave generated by the fixing point aᵤ, and
as a dotted line, a second deformation wave generated by the fixing point aᵤ₊₁.

The superposition of the two waves, in the simplified case of a medium without dissipation with bars sized in the way explained above, is represented in dashes. It is thus noted that, in all of the secondary bars 12 and 13, the deformation waves interfere and are annulled. However, the stress within them, in particular on their ends, remains significant. It can therefore be said that the relative rigidity of the secondary bars 12 and 13 is increased, which limits the propagation of the deformation waves generated at the fixing points aᵤ and aᵤ₊₁ to the secondary bars 12 and 13 located between the fixing points aᵤ and aᵤ₊₁.

Anisotropic Propagation Medium for the Transverse Waves Between the Primary Bᵤ₀ and Secondary Bᵤ₁ Bars by the Tertiary Bars Bᵤ₂

Through the diagram of FIG. 3, the interest of the tertiary bars 14 which create propagation paths which are favourable for the deformation waves coming from the mechanical connections of the fixing 1 to the frame 3 to the operating nodes 1000 and 1100 of the first type nᵤ₁ is understood (see the waves represented in the bars 14 illustrated in FIG. 3). The presence of such paths is highly preferable, as, given the phase shifts imposed by the proposed fixing 1, the deformation waves at the connecting points aᵤ and aᵤ₊₁ would destructively interfere with the arriving/returning waves of the primary bars 11, this having the consequence of increasing the relative rigidity of the primary bars 11, and therefore of increasing the energy transfer between the fixing 1 and the piezoelectric resonator 2. For this reason, it is proposed to create a more favourable propagation path (i.e. having an equivalent lineic rigidity), such that the deformation wave mainly propagates in this path. To maximise the transfer of the deformation wave between the secondary 12 and 13 and tertiary 14 bars, it is therefore preferable that these are adapted in impedance. However, as by destructive interference, the secondary bars 12 and 13 are made very rigid at the working frequency (see above), it will be sought to produce tertiary bars 14 such as their quadratic moment with respect to the working axis, which is greater than in the primary bars 11.

Thus, by doing so, the waves generated by the fixing points aᵤ and aᵤ₊₁ considered will not modify the equivalent rigidity of the primary bars 11, which will therefore not lead to modification on the power transfer of the resonator 2 to the frame 3 (transfer which must remain minimum).

### Point on Sizing

It is preferable that attention is given to the distance between the connecting points aᵤ and aᵤ₊₁ between the fixing 1 and the resonator 2. Indeed, if the connecting points aᵤ and aᵤ₊₁ are located at distances, such that the total distance Lₜₒₜ between two connecting points is equal to or a multiple of a half-wavelength being able to be generated over the periphery of the resonator 2 in the working frequency band, a favoured resonance can appear on the contours of this. For example, in the case of disc-type resonators, if three contact points are used, while this operates on a radial mode, then the distance from the points in pairs is

$${L}_{tot} = \frac{2 π}{3} R$$

with R the radius of the resonator 2. Yet, 2R corresponds to the main characteristic working length. As Lₜₒₜ is close to this length, it can be assumed that a favourable contour mode can be excited, which is not desired. Therefore, it will be preferred to work with four elementary cells and therefore four fixing points of the resonator 2 on the fixing 1.

The invention proposed is therefore based on three distinct principles, which are:
minimising the energy transmitted to the fixing 1 by the resonator 2 by using a slightly rigid primary bar at the working frequency.
developing substantially zero extended connecting displacement nodes at the mechanical junctions between consecutive cells which make it possible to interface the fixing 1 with the frame 3, and thus isolate the resonator 2 from its working environment 3, and
creating favourable propagation paths via the tertiary bar 14, such that the mechanical deformation wave generated by an adjacent anchoring cannot interfere with the primary bar 11.

As has been able to be seen above, to minimise the energy transmitted from the resonator 2 to the fixing 1, the primary bars 11 are sized to resonate at a frequency in the working frequency range of the resonator. The primary bars 11 are, as embedded-embedded substantially at the operating nodes 1000 and 1100 of the first type nᵤ₁, and each fixing point aᵤ of the resonator 2 to the fixing 1 is substantially located in the middle of the primary bar 11 which carries it. The resonance frequency of these primary bars 11 is chosen, such that it corresponds to their main resonance mode, by considering each primary bar 11 in itself, i.e. not mechanically linked to the resonator 2. For more precisions in the sizing of the primary bars 11, the optional connection pad or lug 110 can be included, as a minimum, the mass of this pad, such that the “primary bar 11+connection pad” assembly actually resonates at the desired frequency. Moreover, in addition to respecting the resonance frequency, each primary bar 11 is chosen to be as flexible as possible in the limit of the technical and economic possibilities, in order to limit the energy transmitted to the fixing 1 even more.

Moreover, by creating a transmission mechanical impedance rupture at the operating nodes 1000 and 1100 of the first type nᵤ₁, little energy is transmitted to the rest of the fixing 1, i.e. to the assembly formed of the primary 11 and tertiary 14 bars.

Then, by producing the holding device 1 symmetrically, even periodically, around the resonator 2, the deformation waves produced in the fixing 1 are destructively interfered, which makes it possible to both increase the equivalent rigidity of the secondary bars 12 and 13, but also to create extended zero connecting displacement nodes at the mechanical connections between consecutive elementary cells. These are these operating nodes 1200 and 1300 of the second type nᵤ₀ which are advantageously used to mechanically interface the fixing 1 with the frame 3.

Finally, such that the deformation waves circulating in the secondary bars 12 and 13 does not disrupt and increase the equivalent rigidity of the primary bars 11, which would increase the energy supplied to the fixing 1 by the resonator 2, the propagation of the deformation waves between the primary bars 11 and the secondary bars 12 and 13 is minimised via using tertiary bars 14 as waveguides, which represent more favourable energy transfer paths. Indeed, the thickness of the tertiary bars 14 can be chosen as large before the thickness of the primary bars 11. Ideally, each tertiary bar 14 is adapted in mechanical impedance with the secondary bars 12 and 13 such that most of the energy coming from the secondary bars is absorbed by the tertiary bars 14 and not by the primary bars 11. Effectively, as the rigidity of the secondary bars 12 and 13 is increased at the operating frequency by destructive interference, it will be sought to make the tertiary bars 14 more rigid than the primary bars 11. As regards the primary bars 11, to minimise their rigidity, they are preferably chosen for purposes before the thickness of the secondary bars 12 and 13, which accentuates the mechanical impedance rupture and limits the energy exchanges between primary 11 and secondary 12 and 13 bars, which is also advantageous.

The invention proposed addresses the main problem of mechanically holding a piezoelectric resonator 2 while limiting the impact of its holding device 1 for longitudinal- and/or transverse-type working modes. Contrary to the solutions stated in the introduction, the holding device 1 according to the first aspect of the invention uses the interfering of the waves propagating within it to minimise the energy transferred from the resonator to the frame 3, and to create extended nodes facilitating the connection of the holding device 1 to the frame 3, while limiting the energy transfer to the frame 3. In doing so, the dimensions of the holding device 1 can be considered reduced. The same principle of the holding device 1 described above can be adapted to several geometries (dimensions and shape) of resonators 2 and can be made of several different materials.

The part below has, as an example, calculation rules for the sizing of a holding device 1 adapted to a resonator 2 taking the form of a disc.

### Case of a Disc-Type Resonator Operating on a Radial-Type Main Mode

A fixing device 1 according to the first aspect of the invention is given below, for the example, which makes it possible to hold a circular-shaped piezoelectric resonator 2 operating on a radial-type vibratory mode. In order to hold the resonator 2 so as, as a minimum, isostatic, a minimum of three fastening points 110 are necessary. However, as seen above, the distance between the fastening points 110 over the periphery of the resonator 2 is thus π/32R, and, as π/3 is close to 1, it can easily be assumed that a diametral mode will interfere in the operating band between the resonance frequency and the antiresonance frequency of the resonator 2. A solution consists of the addition of a fourth fastening point 110, which reduces the distance between the fastening points and makes it possible to isolate the diametral resonance mode at a greater frequency, far from the use band. With four fastening points, the holding device 1 can be such as illustrated in FIG. 4.

The first parameters which are important to consider, are the working frequency band of the fixing 1 developed and also the dimension Lₜₒₜ available for the production of an elementary cell (or pattern) of the holding device 1. These two parameters are directly linked to choosing the resonating piezoelectric material and to the dimensions of it.

In the present example, below, the holding device 1 is sized for a circular resonator, 25 mm in diameter, constituted of a PZT (lead zirconate titanate)-based piezoelectric material, known in commercial name C213 from Fujiceramic®. This resonator thus has a resonance frequency of 89 kHz and antiresonance frequency of 103 kHz. It is therefore in this frequency range, that the bars 11, 12, 13 and 14 of each elementary cell 10a, 10b, 10c and 10d of the holding device 1 must be adapted. In addition, as has been chosen for four holding points, it is known that for a holding device 1 located at an average distance of 1.5 mm from the circular outer perimeter of the resonator, Lₜₒₜ≅22 mm.

Then, choosing the material constituting the holding device 1 can come. A material commonly used in electronics is FR-4 TG150. Its interest is that it has good dielectric properties and can be purchased in copper-covered wafers. This makes it possible to obtain two conductive parallel planes which are electrically isolated from one another, which are interesting for the electrical reconnections between the piezoelectric resonator 2 and the frame 3 through the fixing 1.

FR-4 TG150 has a Young's modulus E of 22 GPa and a density ρ of 1900 kg/m³. In a process of simplifying the method, it is chosen to use standard FR-4 wafers, which have a height of 1.55 mm, and which are covered with a copper layer, 70 μm thick. As the thickness of copper is low before the height of FR-4, FR-4 will only be considered for the mechanical sizing. In addition, although this is a composite material, it will be considered as isotropic for the sizing of the bars Bᵤ₀, Bᵤ₁ and Bᵤ₂. In addition, it will not be considered for the example, that rectangular cross-sectional bars, simpler to produce during the machining of an FR-4 wafer with a drill or a laser.

### Sizing of the Primary Bars Bᵤ₀

The first set of bars to be sized corresponds to all of the primary bars, referenced 11 and referenced Bᵤ₀. Indeed, their length and their thickness will size all of the rest of the holding device 1. Thus, it is assumed that, for manufacturing reasons, the thickness (along y in the diagram of FIG. 1) of the primary bars Bᵤ₀ is e₀=0.5 mm. Their length must thus be calculated. such that they can resonate at a frequency in the chosen operating/working band of the resonator 2. The methods making it possible to determine the deformed view of beams dynamically are formulated through Euler-Bernoulli beam theory, the fundamental equation of a beam bending along the axis y is thus as follows:

$$\frac{{EI}_{z}}{ρ S} \frac{{\partial }^{4} y ( x , t )}{\partial {x}^{4}} + \frac{{\partial }^{2} y ( x , t )}{\partial {t}^{2}} = f ( x , t )$$

With l_{z} the associated bending quadratic moment, S the cross-section of the beam, y the displacement and f the outer force density. In this case, a force is applied sporadically, the zero outer force density will be considered. In addition, it is known in advance, that it will be sought to make the beam resonate, and more specifically, the primary bar 11, on its first mode, and knowing that this will be linked in its centre at the resonator 2. As each elementary cell 10a, 10b, 10c and 10d is fully symmetrical, the conditions at the limits are the same. The solutions to the equation above are thus of the form:

$$y ( x , t ) = ( A sin ( β x ) + B cos ( β x ) + C sinh ( β x ) + D cosh ( β x ) ) {e}^{i ω t + Φ}$$

$$β = \sqrt{ω} * \text{?}$$

$$\text{?} \text{indicates text missing or illegible when filed}$$

Through construction, the primary bar, referenced 11 referenced Bᵤ₀, is considered as embedded on its two ends. Thus, at the limits of the primary bar 11, almost zero transverse and angular displacements can be considered. Therefore:

$$y ( x ( {n}_{u 1} ) , t ) ≅ 0$$

$${θ ( x ( {n}_{u 0} ) , t ) = \frac{\partial y ( x , t )}{\partial x} \vert}_{x = x ( {n}_{u 1} )} ≅ 0$$

Knowing the conditions at the limits, and the form of the solution introduced above, it is found that the specific pulsations of each primary bar 11 are the solutions of the equation:

$$tan β {l}_{0} + tanh β {l}_{0} = 0$$

The solution of the first vibration mode which corresponds to the mode that is sought to implement is thus given by the following equations:

$$β * {l}_{0} = 4.73$$

$${l}_{0} = \frac{4.73}{\sqrt{ω}} \sqrt[4]{\frac{{EI}_{z} ( {B}_{u 0} )}{ρ {S}_{0}}}$$

Knowing the thickness (0.5 mm) and the height of the bars (1.55 mm), their flex modulus and their cross-section can be calculated, such that:

$${I}_{z} ( {B}_{u 0} ) = \frac{{he}_{0}^{3}}{12}$$

$${S}_{0} = {he}_{0}$$

By using the formula described above and by considering a resonance frequency of the bar of 95 kHz (that is a pulsation in the working frequency band). A length l₀ of the primary bars Bᵤ₀ is found, equal to 4.3 mm.

### Sizing of the Secondary Bars Bᵤ₁

With the architecture of the holding device being periodical, it is sought to make the elementary cell loop. Thus, in the case where it is considered that the holding device 1 is located at a distance of around 1.5 mm with respect to the radius of the resonator 2, and that this is repeated 4 times, it is thus found that the average length available is given by:

$${L}_{tot} = ( {R}_{PR} + 1.5 e - 3 ) * 2 * \frac{π}{4} ,$$

where R_{PR} is the radius of the resonator 2.

In the example, in this case, Lₜₒₜ is found, which is equal to 22 mm. Considering that a portion of 4.3 mm is already used by the primary bar of each elementary cell, it is known that the two secondary bars 12 and 13 of each elementary cell totaling a length of 17.7 mm. Thus, the length l₁ of one single secondary bar Bᵤ₁ is 8.85 mm. In this way, the holding device 1 loops on itself, around the resonator 2.

The secondary bars 12 and 13 are linked over their perimeter to the frame 3 at the operating nodes 1200 and 1300. The connection between the secondary bars 12 and 13 and the frame 3 is considered as sporadic. In addition, the bars are held on their second side via a bar considered as very rigid, substantially at a zero displacement node 1000 or 1100. Thus, the bars Bᵤ₁ are considered as embedded, on the one hand, and sporadically linked, on the other hand. By reusing the equations developed above and the flex modulus equation, the thickness of the bars Bᵤ₁ can be calculated, such that it corresponds to a half-wavelength at a frequency taken in the operating band of the resonator 2, and preferably taken substantially in its centre or its geometric centre:

$${e}_{1} = \frac{\sqrt{\frac{12 ρ}{E}} {( {L}_{tot} - {l}_{0} )}^{2}}{{4.73}^{2}} ω$$

Thus, in the example case, it is found that the secondary bars Bᵤ₁ have a thickness of 3.4 mm for an average bend radius of 14.5 mm with respect to the centre of the resonator 2. With these dimensions, extended zero displacement nodes are created at the fixing points nᵤ₀ of the holding device 1 to the frame 3.

### Sizing of the Tertiary Bars Bᵤ₂

For what is the last type of bars of the elementary cells of the holding device 1, i.e. the tertiary bars 14, referenced Bᵤ₂, it is sought to make it adapted, in impedance, to the secondary bars Bᵤ₁, such that, the deformation waves propagate from the secondary bars Bᵤ₁ to the tertiary Bᵤ₂ and primary Bᵤ₀ bars mainly propagate into the tertiary bars Bᵤ₂ and slightly into the primary bars Bᵤ₀. However, in the secondary bars Bᵤ₁, the deformation waves are destructively interfered, which makes these bars very rigid at the studied frequency. Ultimately, in order to be adapted in impedance, it would be necessary that the tertiary bars Bᵤ₂ are also rigid, which would lead to very thick bars. Therefore, it will be sought just to find a thickness of these tertiary bars Bᵤ₂ such that their quadratic moment is greater than the quadratic moment of the primary bars Bᵤ₀. For example, a factor 10 can be considered (at least 4 and advantageously more than 10). Therefore:

$${I}_{Z} ( {B}_{u 2} ) = 10 {I}_{z} ( {B}_{u 0} )$$

$${e}_{2} = \text{?}$$

$$\text{?} \text{indicates text missing or illegible when filed}$$

It is thus found that all of the tertiary bars Bᵤ₂ will have a thickness of 1.07 mm according to this criterion. Naturally, the ratio 10 is not fixed and other factors can be used, in particular, if it is sought to reduce the surface area used by the holding device 1, or also to make the holding device 1 even more efficient, by making the tertiary bars Bᵤ₂ even more rigid.

FIG. 4 represents the support sized by means of the criteria above. By using the copper layers present on FR-4, electrical connection tracks connecting the top electrode of the resonator with the frame can be achieved simply, by means of conventional methods for manufacturing printed circuit boards, often called PCBs. In the same way, tracks connecting the bottom electrode of the resonator with the frame can also be manufactured.

The frame can be a continuity of the material used for the fixing, for example, in the case of using a PCB as described in this example, the PCB can continue to accommodate the control electronics of the resonator and other electronic functions.

Through the example given above, the sizing of a holding device 1 for a circular-type resonator 2 has been given. The process is applicable for other forms of resonators 2, but also with other forms of bars 11, 12, 13 and 14, circular cross-sectional bars can be considered, of the IPN type, or constituted of different materials.

An alternative to the example given above consists of not working with a circular resonator 2, but with a resonator having any shape. By correctly using the process presented above, it is thus possible, for a person skilled in the art, to actually size the three types of elementary bars constituting the holding device 1 according to the first aspect of the invention, such that this holds the resonator 2 by producing few losses and by transmitting little energy to the frame 3. These three types of elementary bars are not necessarily of square cross-sections, but can have other cross-sectional shapes: IPN, round, trapezoidal, etc. In addition, the three types of bars Bᵤ₀, Bᵤ₁ and Bᵤ₂ can be made of different materials.

Another alternative consists of not placing the holding device 1 on the outer border of the resonator 2, but on either side of this, on these flat faces. In doing so, it is possible to use materials which are directly electrical conductors (for example, brass) and which have better mechanical properties. The only limitation for placing connecting points a, between the holding device 1 and the resonator 2 is that, at these points, the holding device 1 undergoes substantially phased transverse deformations (at plus or minus 30°), and substantially of the same amplitude (at plus or minus 20%).

The fixing device 1 can also be placed on the internal part of a resonator 2 taking the form of a hollow disc or ring, and not necessarily along the outer perimeter of it, as is the case in the example given above. Likewise, the resonator 2 can have the form of a washer/of a tube, and this washer/tube can be mechanically held by a holding device 1 according to the first aspect of the invention by its inner perimeter.

Moreover, in the case of using a piezoelectric resonator 2 for energy conversion, it is possible to make the fixing device 1 directly of the material serving as a support to the electronic circuit (ceramic, PCB).

It is also possible to make the fixing 1 of the same material as the resonator 2, and in particular, in continuity with it.

Another alternative consists of using the holding device 1 in matrix form for a multitude of resonators 2. Thus, the interference of the acoustic waves is no longer only produced by the mechanical connecting points of one single resonator, but also by the mechanical connecting points of other resonators 2, having for example, substantially the same features. The interest of working in matrix form is to be able to work at a high frequency, this being defined by the dimension of the resonator 25, while using a large resonator 2 surface area, which makes it possible to increase the power of a converter comprising the holding device 1 in matrix form. FIG. 5 has a diagram implementing such a matrix structure.

The holding device 1 has first been considered for power electronics and using bulk piezoelectric resonators 2. It forms an interesting assembly with the piezoelectric resonator component 2 and makes it possible to massify its use. As said in the introduction, power converters are omnipresent and their frequency increase poses problems. If the solution of using piezoelectric resonators 2 proves to actually be relevant, the holding device according to the first aspect of the invention raises the issue of “how to implement these vibrating components”, without disrupting their vibration and without transmitting vibrations to the frame 3.

It must also be noted that it is absolutely possible to use the holding device 1 according to the first aspect of the invention on radiofrequency systems, rather than on power converters. This would also make it possible to reduce their surface footprint.

The invention is not limited to the embodiments described above and extends to all the embodiments covered by the invention.

1. A holding device for a piezoelectric resonator, the holding device comprising at least two elementary cells configured to be mechanically linked to one another, and to be distributed over a perimeter of the piezoelectric resonator, at least one elementary cell comprising four bars of which:
a primary bar by which the holding device is configured to be mechanically linked to the piezoelectric resonator,
two secondary bars, of which:
a first secondary bar mechanically linked to the primary bar of the at least one elementary cell, mechanically linked to a second elementary cell adjacent to the at least one elementary cell, and configured to be mechanically linked to an outer frame, and
a second secondary bar mechanically linked to the primary bar of the at least one elementary cell, mechanically linked to a third elementary cell adjacent to the at least one elementary cell, and configured to be mechanically linked to the outer frame, and
a tertiary bar mechanically linking the first secondary bar and the second secondary bar.

2. The holding device according to claim 1, wherein the primary bar of the at least one elementary cell is of dimensions such that, with a piezoelectric resonator configured to vibrate in a determined frequency band, the primary bar resonates, at plus or minus 20% with the vibrations of the piezoelectric resonator for any excitation frequency in the determined frequency band.

3. The holding device according to claim 1, wherein at least one from among the first and second secondary bars is of dimensions such that it has a length substantially equal to a multiple of a half-wavelength for a chosen excitation frequency located in a determined frequency band, and has, with respect to a longitudinal axis, a quadratic moment at least four times greater than a quadratic moment of the primary bar with respect to it's a longitudinal axis of the primary bar.

4. The holding device according to claim 1, wherein the tertiary bar, is of dimensions such that the tertiary bar has a length substantially equal to the length of the primary bar, a thickness greater than a thickness of the primary bar, and is adapted in mechanical impedance with the first and second secondary bars.

5. The holding device according to claim 1, wherein the at least two elementary cells are configured to be distributed over the perimeter of the piezoelectric resonator by forming a structure closed on itself, the second elementary cell which is mechanically linked to the first secondary bar, is adjacent, in said closed structure, to the at least one elementary cell, and the third elementary cell which is mechanically linked to the second secondary bar of the at least one elementary cell, is adjacent, in said closed structure, to the at least one elementary cell, the second and third elementary cells mechanically linked to the at least one elementary cell being able to be different from one another.

6. The holding device according to claim 2, wherein the primary bar is sized so as to resonate in a first mode, at plus or minus 20%, advantageously plus or minus 10%, for said any frequency located in the determined frequency band.

7. The holding device according to claim 1, wherein at least one bar from among the four bars is constituted with the basis of at least one material chosen from among:
a metal, such as brass or copper,
plastic,
a ceramic,
a crystal, and
a glass fibre-reinforced epoxy resin composite.

8. The holding device according to claim 1, wherein at least one bar from among the four bars comprises an isolating material and one or more thin metal layers separated by the isolating material.

9. The holding device according to claim 1, wherein at least one bar is constituted with the basis of a same piezoelectric material as that in which constitutes the piezoelectric resonator.

10. The holding device according to claim 1, wherein the primary bar is configured to be mechanically linked to the piezoelectric resonator at a first connecting points located between a first end and a second end of the primary bar.

11. The holding device according to claim 1, wherein the primary bar is configured to be mechanically linked to the piezoelectric resonator through a lug, a mass of the lug being considered for a sizing of the primary bar.

12. The holding device according to claim 1, wherein;
the first secondary bar of the at least one elementary cell is mechanically linked by a first of its two ends to a first end of the first bar of the at least one elementary cell, is mechanically linked by a second of its two ends both to a second end of the secondary bar of the third elementary cell which, from among the at least two elementary cells, is adjacent to the at least one elementary cell, and is configured to be mechanically linked to the outer frame, and
the second secondary bar of the at least one elementary cell is mechanically linked by a first of its two ends to the second end of the primary bar of the at least one elementary cell, is mechanically linked by a second of its two ends both to a second end of the first secondary bar of the second elementary cell which, from among the at least two elementary cells, is adjacent to the elementary cell considered, and configured to be mechanically linked to the outer frame.

13. The holding device according to claim 12, wherein the tertiary bar of the at least one elementary cell mechanically links the first end of the first secondary bar of the at least one elementary cell and a first end of the second secondary bar of the third elementary cell.

14. The holding device according to claim 1, wherein the tertiary bar of each of the at least two elementary cells is located to the right and at a distance from the primary bar of the at least one elementary cell, and is configured to be located, relative to the perimeter of the piezoelectric resonator that the tertiary bar of the least two elementary cells contributes to holding, at a greater distance than the primary bar of the at least one elementary cell.

15. The holding device according to claim 1, wherein the at least two elementary cells are distributed over the perimeter of the piezoelectric resonator, such that the piezoelectric resonator, by operating, exerts an excitation of a same amplitude at plus or minus 20% and/or of the same phase, at plus or minus 30°.

16. The holding device according to claim 1, wherein each primary bar has a thickness at least 10 times greater than a deformation amplitude that it undergoes due to operation of the piezoelectric resonator.

17. A power converter comprising a holding device according to claim 1 and at least one piezoelectric resonator.

18. (canceled)

19. The power converter according to claim 17, wherein the at least one piezoelectric resonator is configured to vibrate in at least one of first vibration modes being one of a transverse vibration mode and/or a longitudinal vibration mode.

20. The power converter according to claim 17, wherein the at least one piezoelectric resonator has a resonance frequency and an antiresonance frequency, different from one another, and is configured to operate between its resonance frequency and its antiresonance frequency.

21. A method for sizing a holding device according to claim 1, comprising:
sizing at least one primary bar of one of the two elementary cells such that, with a piezoelectric resonator configured to vibrate in a determined frequency band, the at least one primary bar resonates, at plus or minus 20% with the vibrations of the piezoelectric resonator for any excitation frequency located in said determined frequency band, and/or
sizing at least one from among the first and second secondary bars of at least one of the at least two elementary cells such that the at least one of the first and second secondary bars has a length substantially equal to a multiple of a half-wavelength for a chosen excitation frequency located in the determined frequency band, and have, with respect to a longitudinal axis of the at least one of the first and second secondary bars, a quadratic moment at least four times greater than a quadratic moment of the primary bar with respect to its longitudinal axis, and/or
sizing the tertiary bar of at least one of the at least one of the at least two elementary cells such that the sized tertiary bar has a length substantially equal to a length of the primary bar of the at least one elementary cell, a thickness greater than a thickness of the primary bar of the at least one elementary cell, and is adapted in mechanical impedance with the first and second secondary bars of the at least one elementary cell.
